(19) United States
(12) Patent Application Publication
(10) Pub. No.: US 2026/0062834 A1
(43) Pub. Date: Mar. 5, 2026

(54) ACTIVE SIC HEATING WITH ZONALITY CONTROL FOR EPI CHAMBER THERMAL PROFILE ADJUSTING

(71) Applicant: Applied Materials, Inc., Santa Clara, CA (US)

(72) Inventor: Zhepeng CONG, San Jose, CA (US)

(21) Appl. No.: 19/313,256

(22) Filed: Aug. 28, 2025

Related U.S. Application Data
(60) Provisional application No. 63/689,511, filed on Aug. 30, 2024.

(51) Int. Cl. C30B 25/10; C30B 25/16; H01L 21/66; H01L 21/67

(52) U.S. Cl. CPC C30B 25/105; C30B 25/16

(57) ABSTRACT

A processing chamber includes a chamber body, a lid disposed over the chamber body, and one or more first laser devices disposed over the lid. The one or more first laser devices are configured to emit light having a wavelength of about 380 nm to about 600 nm. A first isolation plate is disposed within an internal volume that is at least partially defined by the chamber body. A semi-translucent layer is disposed over the first isolation plate. The semi-translucent layer configured to absorb at least part of the light emitted from the one or more first laser devices.

### CROSS-REFERENCE TO RELATED APPLICATIONS

This application claims the benefit of U.S. Provisional Application 63/689,511 filed on Aug. 30, 2024, which is hereby incorporated by reference.

### BACKGROUND

### Field

The present disclosure relates to semiconductor processing chambers, and more particularly, flow thermal profile adjusting for a gas flow pattern during an epitaxy process.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

Typically, the isolation plate is made from quartz which has a high transmission to IR light. Even though IR light can be used to heat the substrate locally, heating the substrate locally results in defects. Therefore, there is a need in the art to control the isolation plate temperature for process modulations to prevent defects.

### SUMMARY

In one or more embodiments, a processing chamber includes a chamber body, a lid disposed over the chamber body, one or more first laser devices disposed over the lid, the one or more first laser devices configured to emit light having a wavelength of about 380 nm to about 600 nm, a first isolation plate disposed within an internal volume that is at least partially defined by the chamber body; and a semi-translucent layer disposed over the first isolation plate, the semi-translucent layer configured to absorb at least part of the light emitted from the one or more first laser devices.

In one or more embodiments, a method includes depositing an epitaxial film on a first substrate in a processing chamber, the processing chamber including one or more laser devices, a semi-translucent layer disposed over the first substrate, the semi-translucent layer configured to absorb at least a portion of the light emitted from the one or more laser devices, and a scanning laser system including the one or more laser devices, reflective mirrors that are aligned with each of the one or more laser devices, and a controller coupled to the one or more laser devices and the reflective mirrors, determining the epitaxial film has a non-uniform thickness, the determining that the epitaxial film has the non-uniform thickness comprising determining one or more locations on the first substrate in which the thickness of the epitaxial film is different than a target thickness, and adjusting a temperature of the semi-translucent layer, the adjusting of the semi-translucent layer comprising steering, by the controller using the reflective mirrors, the one or more laser devices to one or more locations on the semi-translucent layer that correspond to the one or more locations of the first substrate in which the thickness of the epitaxial film is different than the target thickness during deposition of the epitaxial film on a subsequent substrate.

In one or more embodiments, a method for processing a substrate includes determining a temperature of a semi-translucent layer disposed over an isolation plate of a processing chamber using one or more sensors, and based on determining that the semi-translucent layer is outside of a target temperature range, adjusting the temperature of the semi-translucent layer by adjusting a power of one or more laser devices, the one or more laser devices configured to emit light having a wavelength of about 380 nm to about 600 nm, and the semi-translucent layer configured to absorb at a portion of the light emitted by the one or more laser devices.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a schematic side cross-sectional view of a processing chamber, according to one or more embodiments.

FIG. 3 is a schematic block diagram view of a method of substrate processing, according to one or more embodiments.

FIG. 4 is a schematic block diagram view of a method 400 of substrate processing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

As noted above, the processing of substrates may include depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

In order to improve process tuning for gas flow patterns over a substrate, isolating plates and parallel design blocks are used. Typically, the isolation plate is made from quartz which has a high transmission, such as 90% or higher, to infrared (IR) light and/or blue light. Even though IR light can be used to heat the substrate locally, heating the substrate locally results in defects. Embodiments herein relate to heating the substrate using indirect heating (secondary radiation) to mitigate the defects caused by local heating of the substrate.

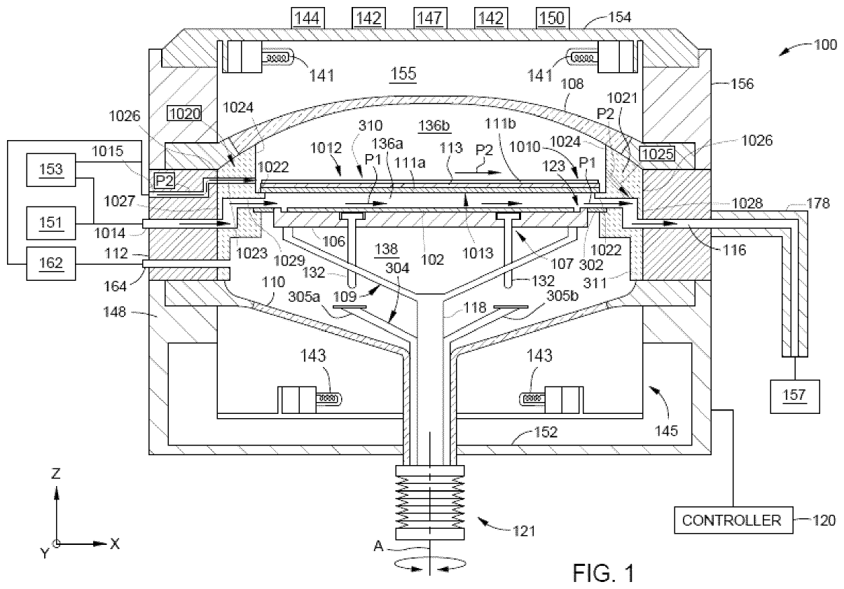

FIG. 1 is a partial schematic side cross-sectional view of a processing chamber 100, according to one or more embodiments. The processing chamber 100 is a deposition chamber. In one or more embodiments, the processing chamber 100 is an epitaxial deposition chamber. In one or more embodiments, the processing chamber 100 is utilized to grow an epitaxial film on a substrate 102. The processing chamber 100 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 109, an upper plate 108 (such as an upper window and/or an upper dome), a lower plate 110 (such as a lower window and/or a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

In one or more embodiments, one or more first laser devices 142, a second laser device 144, a sensor 147 (such as a pyrometer), and a spot heater 150 (e.g., a laser spot heater) are disposed on the lid 154, and configured to be directed towards the substrate 102. In one or more embodiments, the second laser device 144 is a laser that emits light having a wavelength of about 800 nm to about 1000 nm, for example 970 nm. The first laser devices 142 are lasers configured to emit light having a wavelength of about 380 nm to about 600 nm, for example 460 nm (e.g., blue light). In one or more embodiments, the first laser devices 142 are polarized. In one more embodiments, the first laser devices 142 have a first polarization wavelength of about 450 nm to about 475 nm. In one more embodiments, the first laser devices 142 have a second polarization wavelength of about 580 nm to about 620 nm. Although two first laser devices 142, one second laser device 144, and one sensor 147 are illustrated in FIG. 1, this is for example purposes only and any suitable quantity of first laser devices 142, second laser devices 144, and sensor(s) 147 may be used. In one or more embodiments, the second laser device 144 is optional. The wavelengths of the respective sources are selected for absorption/transmission through specific chamber components and/or specific substrate materials.

The substrate support 109 includes a susceptor 106 that is disposed between the upper plate 108 and the lower plate 110, and a shaft 118. The susceptor 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the susceptor 106. The pre-heat ring 302 is supported on a ledge of the lower liner 311. A stop 304 includes a plurality of arms 305a, 305b that each include a lift pin stop on which at least one of the lift pins 132 can rest when the susceptor 106 is lowered (e.g., lowered from a process position to a transfer position).

The internal volume has the susceptor 106 disposed therein. The susceptor 106 includes a top surface on which the substrate 102 is disposed. The susceptor 106 is attached to the shaft 118. The shaft 118 is connected to a motion assembly 121. The motion assembly 121 includes one or more actuators and/or adjustment devices that provide movement and/or adjustment for the shaft 118 and/or the susceptor 106.

The susceptor 106 may include lift pin perforations 107 disposed therein. The lift pin perforations 107 are sized to accommodate a lift pin 132 for lifting of the substrate 102 from the susceptor 106 either before or after a deposition process is performed.

A chamber kit 1010 includes a first isolation plate 111a having a first outer face 1012 and a second outer face 1013 opposing the first outer face 1012. The second outer face 1013 faces the susceptor 106. The chamber body includes an upper liner 1020 and the lower liner 311. The upper liner 1020 includes an annular section 1021. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. At least part of the annular section 1021 of the upper liner 1020 is aligned with the first extension 1027 and the second extension 1028. In the embodiment shown in FIG. 1, a lowermost end of the first isolation plate 111a is aligned above a lowermost end of the upper liner 1020. In one or more embodiments, as shown in FIG. 1, the lowermost end of the first isolation plate 111a is part of the second outer face 1013, and the lowermost end of the upper liner 1020 is part of the first extension 1027 and/or the second extension 1028. The present disclosure contemplates that the lowermost end of the upper liner 1020 can be part of the lower surface 1029.

The first isolation plate 111a is in the shape of a disc, and the annular section 1021 is in the shape of a ring. It is contemplated, however, that the first isolation plate 111a and/or the annular section 1021 can be in the shape of a rectangle, or other geometric shapes. The first isolation plate 111a at least partially fluidly isolates an upper portion 136b of an internal volume from a lower portion 136a of the internal volume. The lower portion 136a is a processing volume. The first isolation plate 111a at least partially defines the processing volume between the plate 111 and the susceptor 106.

The flow module 112 (which can define at least part of one or more sidewalls of the processing chamber 100) includes one or more first inlet openings 1014 (e.g., one or more gas inlets) in fluid communication with the lower portion 136a (e.g., the processing volume) of the internal volume. The flow module 112 includes one or more second inlet openings 1015 (e.g., one or more second gas inlets) in fluid communication with the upper portion 136b of the internal volume. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The first inlet openings 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one or more embodiments, the one or more process gases include silicon hydrides (such as one or more silanes and/or one or more chlorinated silanes) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled (e.g., non-parallel to horizontal) orientation, and/or can include one or more turns (such as the turns shown for the one or more first inlet openings 1014 and the one or more gas exhaust outlets 116).

During a deposition operation (e.g., an epitaxial growth operation), the one or more process gases P1 flow through the one or more first inlet openings 1014, through the one or more gaps, and into the lower portion 136a to flow over the substrate 102 in a gas flow path between the plate 111 and the susceptor 106. During the deposition operation, one or more purge gases P2 flow through the one or more second inlet openings 1015, through the one or more inlet openings 1023 of the upper liner 1020, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116. The one or more process gases P1 can include a deposition precursor, a carrier gas, an etchant gas, a cleaning gas, and/or a mixture thereof, for example.

The present disclosure also contemplates that one or more purge gases can be supplied to the purge volume 138 (through the plurality of purge gas inlets 164) during the deposition operation, and exhausted from the purge volume 138.

A plate apparatus includes the first isolation plate 111a. The first isolation plate 111a is formed of a transparent material. In one or more embodiments, the transparent material includes quartz (e.g., transparent quartz). In one or more embodiments, the first isolation plate 111a is formed of an opaque material (such as opaque quartz (e.g. white quartz, or grey quartz; and/or black quartz), silicon carbide (SiC), graphite coated with SiC, and/or one or more ceramics (such as alumina (aluminum oxide (Al₂O₃)), aluminum nitride (AlN), silicon nitride (Si₃N₄), Boron Nitride (BN), and/or Boron Carbide (B₄C))). The transparent material can facilitate the heating energy from the second laser device 144 and/or the spot heater 150 to pass therethrough and to the susceptor 106 and/or the substrate 102. The opaque material can adjust (e.g., modulate) localized heat transfer of localized heating.

In one or more embodiments, a semi-translucent layer 113 is disposed on the uppermost face of (over) the first isolation plate 111a. In one or more embodiments, the semi-translucent layer 113 may include any material that has a high absorption percentage with respect to the first laser devices 142 (e.g., has a high absorption percentage of blue light). Advantageously, the semi-translucent layer 113 absorbs at least a portion of the light emitted from (laser generated by) the first laser devices 142. For example, the semi-translucent layer 113 absorbs at least part of the light emitted by the first laser devices 142 and allows the substrate 102 to be heated with secondary radiation provided by the absorptivity of the semi-translucent layer 113. Stated differently, the semi-translucent layer 113 has a strong absorption with respect to the wavelength of the first laser devices 142. In one or more embodiments, the semi-translucent layer 113 still allows (e.g., is semi-transparent with respect to) the second laser device 142 and the laser spot heater 150 to pass through and locally heat the substrate 102. This allows a wider heat spectrum to assist on activating different precursors with different absorptions. The material used for the semi-translucent layer 113 and/or the shorter wavelength of the first laser devices 142 allows for adjustment of the temperature of the semi-translucent layer 113, and therefore, allows for control of the temperature difference between inject and exhaust regions. In one or more embodiments the semi-translucent layer 113 may include, but is not limited to, a silicon carbide (SiC) material, such as 4H-SiC, 6H-SiC, or the like. In one or more embodiments, a second isolation plate 111b is positioned over the semi-translucent layer 113. In one or more embodiments, the first isolation plate and the second isolation plate have a thickness of about 0.3 to about 6 mm. In one or more embodiments, the second isolation plate 111b is omitted.

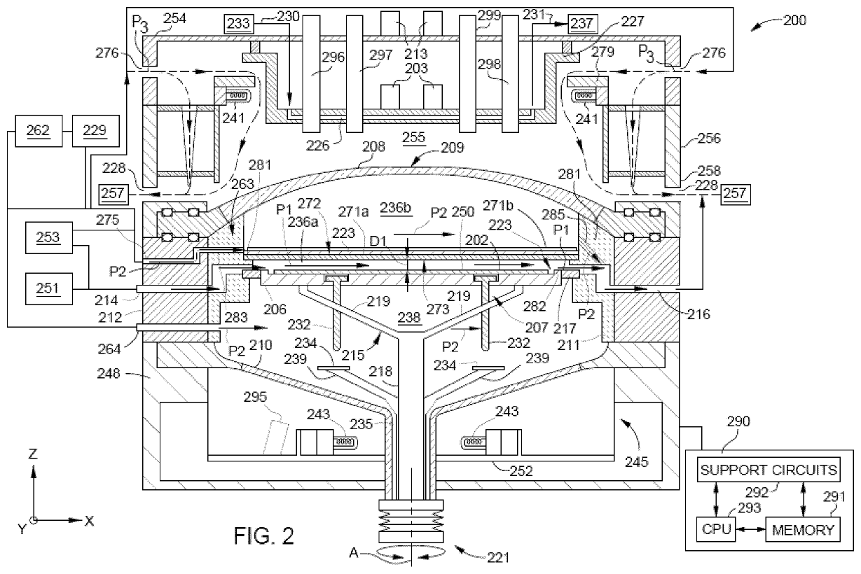

FIG. 2 is a schematic side cross-sectional view of a processing chamber 200, according to one or more embodiments. The processing chamber 200 is a deposition chamber. In one or more embodiments, the processing chamber 200 is an epitaxial deposition chamber. The processing chamber 200 is utilized to grow an epitaxial film on a substrate 202. The processing chamber 200 creates a cross-flow of precursors across a top surface 250 of the substrate 202. The processing chamber 200 is shown in a processing condition in FIG. 2.

The processing chamber 200 includes an upper body 256, a lower body 248 disposed below the upper body 256, and a flow module 212 disposed between the upper body 256 and the lower body 248. The upper body 256, the flow module 212, and the lower body 248 form a chamber body. The upper body 256 is fluidly connected to one or more purge gas inlets P (e.g., a plurality of purge gas inlets) and one or more gas exhaust outlets 228. The one or more purge gas inlets 276 are illustrated as being disposed through a lid 254. However, it is contemplated that the one or more purge gas inlets 276 may be disposed around the chamber on the upper body 256 for strategic flow pathways. The one or more purge gas inlets 276 are disposed above the one or more gas exhaust outlets 228. Purge gas flow within upper heat source module 255 is represented by P3, discussed below. Disposed within the chamber body is a substrate support 215, an upper window 208 (such as an upper dome), a lower window 210 (such as a lower dome), a plurality of upper heat sources 241, and a plurality of lower heat sources 243. The upper window 208 has a central portion 209. In one or more embodiments, the upper heat sources 241 include upper lamps and the lower heat sources 243 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. Furthermore, the placement of the lamps in FIG. 2 is for visual representation and may be located in other strategic areas with an upper heat source module 255 and/or a lower heat sources module 245.

The substrate support 215 is disposed between the upper window 208 and the lower window 210. The substrate support 215 includes a susceptor 206 that supports the substrate 202 and a shaft 218. Other substrate supports (including, for example, a substrate carrier and/or one or more ring segment(s) that support one or more outer regions of the substrate 202) are contemplated by the present disclosure. The plurality of upper heat sources 241 are disposed between the upper window 208 and a lid 254. The plurality of upper heat sources 241 form a portion of the upper heat source module 255. The lid 254 includes a support configured to suspend an inner reflector 227 that houses a plurality of sensor devices 296, 297, 298, 299 disposed therein or thereon and configured to measures temperature(s) within the processing chamber 200. In one example, the sensor devices 296, 297, 298, 299 are pyrometers.

Sensor devices 296, 297, 298, 299 can be disposed on or within the lid 254, and extend through the inner reflector 227. In one or more embodiments, the sensor device(s) 296, 297, 298, 299 monitor the temperature of the substrate 202 and a semi-translucent layer 223 disposed over a first isolation plate 271a. The inner reflector 227 includes a cooling line inlet 230 within the inner reflector 227 that facilitates a reflector cooling operation. In one or more embodiments, the cooling line follows along a snake pattern within a channel 226 embedded in the surface of the reflector. In one or more embodiments, the channel 226 can be an open channel including a recessed groove having a bottom surface and two sidewalls. In one or more embodiments, the channel 226 can be machined into an inner surface of the inner reflector 227. In one or more embodiments, the channel 226 and can be an embedded enclosed channel. For example, the channel 226 can be disposed within one or more hollow tubes embedded into the inner reflector 227. The position of the sensor devices 296, 297, 298, 299 allows for cooling of the sensor devices 296, 297, 298, 299 by cooling lines, 230, 231, thereby improving temperature monitoring accuracy.

The reflector cooling operation can be a continuous, pulsed, and/or timed flow of a cooling fluid through cooling line(s) 230, 231, such as water, refrigerant, or other cooling medium (e.g., cooling flush). Furthermore, the cooling line(s) 230, 231 can help stabilize the inner reflector 227 temperature profile to be less than about 55 degrees Celsius, facilitating fewer thermal variations and less production waste from unstable processing. The cooling line inlet 230 and the cooling line outlet 231 are fluidly connected to a cooling source 233 and a disposal site 237. A lower sensor device 295 is configured to measure temperature(s) within the processing chamber 200. In one or more embodiments, each sensor device 295, 296, 297, 298, 299 is a pyrometer. In one or more embodiments, each sensor device 295, 296, 297, 298, 299 is an optical sensor device, such as an optical pyrometer. The present disclosure contemplates that sensors other than pyrometers may be used. Each sensor device 295, 296, 297, 298, 299 is a single-wavelength sensor device or a multi-wavelength (such as dual-wavelength) sensor device. The lower sensor device 295 is disposed adjacent to the floor 252.

In one or more embodiments, laser devices 213 are disposed on the lid 254 and are aligned with reflective mirrors or prisms 203 (e.g., galvos) that are disposed within the inner reflector 227, thus forming galvo lasers. In one or more embodiments, the reflective mirrors 203 are active mirrors that can be adjusted (steered) to drive the laser beams provided by the laser devices 213 to a location of the semi-translucent layer 223. Although 2 laser devices 213 and reflective mirrors 203 are illustrated in FIG. 2, this is for example purposes only and any quantity of laser devices 213 and reflective mirrors 203 may be used. The laser devices 213, the reflective mirrors 203 and each sensor device 295, 296, 297, 298, 299 are coupled to the controller 290 (or a separate controller unit), and form a scanning laser system. The scanning laser system creates a closed loop system that can control and monitor the temperature of the semi-translucent layer 223. In one or more embodiments, the laser devices 213 are lasers are configured to emit light having a wavelength of about 380 nm to about 600 nm, for example 460 nm (e.g., blue light). In one or more embodiments, the laser devices 213 are polarized. In one more embodiments, the laser devices 213 have a first polarization wavelength of about 450 nm to about 475 nm. In one more embodiments, the laser devices 213 have a second polarization wavelength of about 580 nm to about 620 nm. In one or more embodiments, the laser devices 213 may be red wavelength lasers, blue wavelength lasers, spot heating heatin lasers, or micrometer wavelength lasers (e.g., 2 micrometers to 5 micrometers).

In one or more embodiments, the process chamber 200 includes one or more additional sensor devices, in addition to the sensor devices 295, 296, 297, 298. In one or more embodiments, the process chamber 200 may include sensor devices disposed at different locations and/or with different orientations than the illustrated sensor devices 295, 296, 297, 298, 299. For example, one or more of the sensor devices 295, 296, 297, 298, 299, may be disposed in or on the lid 254 and/or disposed in or on the inner reflector 227. Placement of the sensor devices 295, 296, 297, 298, 299 nearest the measured component enables more accurate and/precise sensing by reducing the distance between the sensor and the object to be measured. By reducing the distance between the sensor and the object to be measured, fewer external parameters may affect the sensing.

The plurality of lower heat sources 243 are disposed between the lower window 210 and a floor 252. The plurality of lower heat sources 243 form a portion of the lower heat source module 245. The upper window 208 is an upper dome and/or is formed of an energy transmissive (e.g., thermally transmissive) material, such as quartz. In one or more embodiments, upper window 208 at least partially physically separates an upper portion of the process chamber 200 (in which the upper heat source module 255 is disposed) from the isolated upper portion 236b of the upper volume 236. The lower window 210 is a lower dome and/or is formed of an energy transmissive (e.g., thermally transmissive) material, such as quartz.

An upper volume 236 and a purge volume 238 are formed between the upper window 208 and the lower window 210. The upper volume 236 and the purge volume 238 are part of an internal volume defined at least partially by the upper window 208, the lower window 210, and one or more liners 211, 263.

The internal volume has the susceptor 206 disposed therein. The susceptor 206 includes a top surface on which the substrate 202 is disposed. The susceptor 206 is attached to a shaft 218. In one or more embodiments, the susceptor 206 is connected to the shaft 218 through one or more arms 229 connected to the shaft 218. The shaft 218 is connected to a motion assembly 221. The motion assembly 221 includes one or more actuators and/or adjustment devices that provide movement and/or adjustment for the shaft 218 and/or the susceptor 206 within the upper volume 236.

The susceptor 206 may include lift pin holes 207 disposed therein. The lift pin holes 207 are each sized to accommodate a lift pin 232 for lifting of the substrate 202 from the susceptor 206 before or after a deposition process is performed. The lift pins 232 may rest on lift pin stops 234 when the susceptor 206 is lowered from a process position to a transfer position. The lift pin stops 234 can include a plurality of arms 239 that attach to a shaft 235.

The flow module 212 includes one or more gas inlets 214 (e.g., a plurality of gas inlets), one or more purge gas inlets 264, and one or more gas exhaust outlets 216. The one or more gas inlets 214 and the one or more purge gas inlets 264 are disposed on the opposite side of the flow module 212 from the one or more gas exhaust outlets 216. A pre-heat ring 217 is disposed below the one or more gas inlets 214 and the one or more gas exhaust outlets 216. The pre-heat ring 217 is disposed above the one or more purge gas inlets 264. The one or more liners 211, 263 are disposed on an inner surface of the flow module 212 and protects the flow module 212 from reactive gases used during deposition operations and/or cleaning operations.

The gas inlet(s) 214 and the purge gas inlet(s) 264 are each positioned to flow a respective one or more process gases P1 and one or more purge gases P2 parallel to the top surface 250 of a substrate 202 disposed within the upper volume 236. The gas inlet(s) 214 are fluidly connected to one or more process gas sources 251 and one or more cleaning gas sources 253. The purge gas inlet(s) 264, 276 are fluidly connected to one or more purge gas sources 262. The one or more gas exhaust outlets 216, 228 are fluidly connected to an exhaust pump 257. The one or more process gases P1 supplied using the one or more process gas sources 251 can include one or more reactive gases (such as one or more of silicon (Si), phosphorus (P), and/or germanium (Ge)) and/or one or more carrier gases (such as one or more of nitrogen (N₂) and/or hydrogen (H₂)).

The one or more purge gases P2, P3, can be supplied using the one or more purge gas sources 262 and can include one or more inert gases (such as one or more of argon (Ar), helium (He), air, and/or nitrogen (N₂)). In one or more embodiments, the air used from in one or more purge gas sources 262 can include dry air, saturated air, or some saturation between dry air and saturated air, such as, for example, ambient air or room air. Furthermore, the temperature(s) of the one or more purge gases P2 and/or P3, supplied by the one or more purge gas sources 262, can be reduced by directing the one or more purge gases P2 and/or P3, towards the one or more chillers 219 to provide a purge of excess heat within the upper portion 236b or the upper heat source module 255. In one or more embodiments, the one or more purge gases P2 and/or P3 may be supplied by a variable speed blower (“VSB”). The VSB can be used as one or more of the one or more purge gas sources 262. One or more cleaning gases supplied using the one or more cleaning gas sources 253 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 216, 228 are further connected to or include an exhaust system, not shown. The exhaust system fluidly connects the one or more gas exhaust outlets 216, 228 and the exhaust pump 257. The exhaust system can assist in the controlled deposition of a layer on the substrate 202. The one or more gas exhaust outlets 228 may be disposed around the processing chamber 200 on a lower half 258 of the upper body 256 to enable purge gas flow towards the outer perimeter of the upper window 208.

In one or more embodiments, the processing chamber 200 includes a first isolation plate 271a (e.g., an isolation plate) having a first face 272 and a second face 273 opposing the first face 272. In one or more embodiments, the first isolation plate 271a is part of a flow guide structure. The second face 273 faces the susceptor 206. The processing chamber 200 includes the one or more liners 211, 263. An upper liner 263 includes an annular section 281 and one or more ledges 282 extending inwardly relative to the annular section 281. The one or more ledges 282 are configured to support one or more outer regions of the second face 273 of the first isolation plate 271a. The upper liner 263 includes one or more inlet openings 283 and one or more outlet openings 285. In one or more embodiments, the first isolation plate 271a is in the shape of a disc, and the annular section 281 is in the shape of a ring. The first isolation plate 271a can be in the shape of a rectangle. The first isolation plate 271a divides the upper volume 236 between the susceptor 206 and the upper window 208 into a lower portion 236a and an upper portion 236b. The lower portion 236a is a processing portion and the upper portion 236b is an isolated portion. In one or more embodiments, the first isolation plate 271a is an isolation plate that at least partially physically isolates the isolated portion (e.g., the upper portion 236b) from the lower portion 236a.

The flow module 212 (which can be at least part of a sidewall of the processing chamber 200) includes the one or more gas inlets 214 in fluid communication with the lower portion 236a. The flow module 212 includes one or more second gas inlets 275 in fluid communication with the upper portion 236b. The one or more gas inlets 214 are in fluid communication with one or more flow gaps between the upper liner 263 and a lower liner 211. The one or more second gas inlets 275 are in fluid communication with the one or more inlet openings 283 of the upper liner 263.

During a deposition operation (e.g., an epitaxial growth operation), the one or more process gases P1 flow through the one or more gas inlets 214, through the one or more gaps, and into the lower portion 236a to flow over the substrate 202. During the deposition operation, one or more purge gases P2, flow through the one or more second gas inlets 275, through the one or more inlet openings 283 of the lower liner 211, and into the upper portion 236b. Also during a deposition operation, one or more purge gases P3, flow through the one or more purge gas inlets 276 and into the upper heat source module 255. The one or more purge gases P2, P3 can flow simultaneously with the flowing of the one or more process gases P1.

The flowing of the one or more purge gases P3 through the upper heat source module 255 facilitates the upper heat source module 255 purging excess heat generated from the plurality of upper heat sources 241, or from the epitaxial growth operation, and thereby maintains a target temperature profile for the upper heat source module 255, the upper window 208, and/or the first isolation plate 271a. For example, there is an indirect temperature effect on the first isolation plate 271a described below. The flowing of the one or more purge gases P2 through the upper portion 236b facilitates reducing or preventing flow of the one or more process gases P1 into the upper portion 236b that would contaminate the upper portion 236b. The one or more purge gases P2 may be directed into the one or more chillers 219 to reduce the temperature of the one or more purge gases P2 to purge excess heat within the upper portion 236b, thereby reducing or preventing flow of the one or more process gases P1 into the upper portion 236b that would otherwise contaminate the upper portion 236b and also provide a cooling effect on the first isolation plate 271a.

In one or more embodiments, a semi-translucent layer 223 is disposed on the uppermost face of the first isolation plate. In one or more embodiments, the semi-translucent layer 223 may include any material that has a high absorption percentage with respect to the laser devices 213 that are disposed within the inner reflector 227. Advantageously, the semi-translucent layer 223 absorbs at least a portion of the light emitted from laser devices 213 and allows the substrate 202 to be heated by secondary radiation provided by the semi-translucent layer 223. In one or more embodiments the semi-translucent layer 223 may include, but is not limited to, a silicon carbide (SiC) material, such as 4H-SiC, 6H-SiC, or the like. Stated differently, the semi-translucent layer 223 may include the same material as the semi-translucent layer 113. In one or more embodiments, an optional second isolation plate 271b may be disposed over the semi-translucent layer 223.

The one or more process gases P1 are exhausted through gaps between the upper liner 263 and the lower liner 211, and through the one or more gas exhaust outlets 216. The one or more purge gases P2 are exhausted through the one or more outlet openings 285, through the same gaps between the upper liner 263 and the lower liner 211, and through the same one or more gas exhaust outlets 216 as the one or more process gases P1. The present disclosure contemplates that that one or more purge gases P2 can be separately exhausted through one or more second gas exhaust outlets that are separate from the one or more gas exhaust outlets 216.

The present disclosure also contemplates that the one or more purge gases P2 can be supplied to the purge volume 238 (through the one or more purge gas inlets 264) during the deposition operation, and exhausted from the purge volume 238.

During a cleaning operation, one or more cleaning gases flow through the one or more gas inlets 214, through the one or more gaps (between the upper liner 263 and the lower liner 211), and into the lower portion 236a. During the cleaning operation, one or more cleaning gases also simultaneously flow through the one or more second gas inlets 275, through the one or more inlet openings 283 of the upper liner 263, and into the upper portion 236b. The present disclosure contemplates that the one or more cleaning gases used to clean surfaces adjacent the upper portion 236b can be the same as or different than the one or more cleaning gases used to clean surfaces adjacent the lower portion 236a.

The processing chamber 200 facilitates separating the gases provided to the lower portion 236a from the gases provided to the upper portion 236b, which facilitates parameter adjustability. Additionally, one or more purge gases and one or more cleaning gases can be separately provided to the upper portion 236b to facilitate reduced contamination of the upper window 208 and/or, in some embodiments, the first isolation plate 271a.

As shown, a controller 290 is in communication with the processing chamber 200 and is used to control processes and methods, such as the operations of the methods described herein.

The controller 290 is configured to receive data or input as sensor readings from a plurality of sensors. The sensors can include, for example: sensors that monitor growth of layer(s) on the substrate 202; sensors that monitor growth or residue on inner surfaces of chamber components of the processing chamber 200 (such as inner surfaces of the upper window 208 and/or the one or more liners 211, 263); and/or, in some embodiments, sensors that monitor temperatures of the semi-translucent layer 223, the susceptor 206, the first isolation plate 271a, and/or the liners 211, 263. The controller 290 is equipped with or in communication with a system model of the processing chamber 200. The system model includes a heating model, a rotational position model, and/or a gas flow model. The system model is a program configured to estimate parameters (such as a gas flow rate, a gas pressure, a processing temperature, a rotational position of component(s), a heating profile, and/or a cleaning condition) within the processing chamber 200 throughout a deposition operation and/or a cleaning operation. The controller 290 is further configured to access and/or store readings and evaluate and/or perform calculations. The readings and calculations include previous sensor readings, such as any previous sensor readings within the processing chamber 200. The readings and calculations further include the stored calculated values from after the sensor readings are measured by the controller 290 and run through the system model. Therefore, the controller 290 is configured to both retrieve stored readings and calculations as well as save readings and calculations for future use. Maintaining previous readings and calculations enables the controller 290 to adjust the system model over time to reflect a more accurate version of the processing chamber 200.

The controller 290 can monitor and control the temperature of the substrate 202 and the semi-translucent layer 223, estimate an optimized parameter, adjust a purge gas flow rate, adjust a chilled purge gas flow rate, initiate a reflector cooling operation, generate an alert on a display, halt a deposition operation, initiate a chamber downtime period, delay a subsequent iteration of the deposition operation, initiate a cleaning operation, detect a cleaning condition for the upper window 208 and/or the first isolation plate 271a, halt the cleaning operation, adjust a heating power, and/or otherwise adjust the process recipe.

The controller 290 includes a central processing unit (CPU) 293 (e.g., a processor), a memory 291 containing instructions, and support circuits 292 for the CPU 293. The controller 290 controls various items directly, or via other computers and/or controllers. In one or more embodiments, the controller 290 is communicatively coupled to dedicated controllers, and the controller 290 functions as a central controller.

The various operations described herein can be conducted automatically using the controller 290, or can be conducted automatically or manually with certain operations conducted by a user.

The controller 290 is configured to control the sensor devices 295, 296, 297, 298, 299, the reflective mirrors 203, the deposition, the cleaning, the rotational position, the heating, and processing gas and purge gas flow paths prior to entry into and through the processing chamber 200, and additional chiller and heater controls, by providing an output to the controls for the heat sources, the gas flow, and the motion assembly 221. The controls include controls for the sensor devices 295, 296, 297, 298, 299, the laser devices 213, the reflective mirrors 203, the upper heat sources 241, the lower heat sources 243, the process gas source 251, the purge gas source 262, the chiller 219, the motion assembly 221, controls to orient gas flow paths, and the exhaust pump 257. In one or more embodiments, the controller 290 is configured to adjust the power of the laser devices 213 and/or adjust the reflective mirrors 203 to steer the laser beam(s) provided by the laser devices 213 to adjust the temperature of the semi-translucent layer 223, and therefore, the substrate 202. Stated differently, the controller 290, based on the temperature of the semi-translucent layer 223 and/or substrate 202 determined by the sensor devices 296, 297, 298, 299, can adjust the power of the laser devices 213 and/or adjust the reflective mirrors 203 to ensure that the substrate 202 is maintained at a target temperature range. Although 4 sensors are used to determine the temperature of the semi-translucent layer 223 and the substrate 202, this is for example purposes only, and it is understood that any suitable quantity of sensor may be used to determine the temperature of the substrate 202 and the semi-translucent layer 223.

The controller 290 is configured to adjust the output to the controls based on the sensor readings, the system model, and the stored readings and calculations. The controller 290 includes embedded software and a compensation algorithm to calibrate measurements. The controller 290 can include one or more machine learning algorithms and/or artificial intelligence algorithms that estimate optimized parameters for the deposition operations and/or the cleaning operations (such as for adjusting a deposition operation (e.g. the process recipe), adjusting a purge gas flow rate, adjusting a chilled purge gas flow rate, initiating a reflector cooling operation, halting the deposition operation, initiating a chamber downtime period, delaying a subsequent iteration of the deposition operation, initiating a cleaning operation, halting the cleaning operation, adjusting a heating power, and/or adjusting the cleaning operation). The optimized parameter can include, for example, a pre-determined temperature on the upper window 208 that initiates a purge gas cycle to remove excess heat generated from processing to adjust the temperature of the upper window 208.

In examples of the disclosure, wavelengths of energy sources can be selected for absorption or transmission through specific materials, including quartz materials, coated materials, or substrate materials. Thus, thermal energy can be provided directly to a substrate, or to a chamber component to facilitate secondary radiation of thermal energy from the irradiated (e.g., heated) chamber component. Such a regime provides improved temperature control. Wavelengths include red light, blue light, or other wavelengths, such as 0.9 micrometers to 5.0 micrometers.

In one or more embodiments, which be optionally combined with one or more lasers of various wavelengths, pyrometers may extend from a chamber lid through a cooled reflector, thereby improving the temperature control of the pyrometer. The improved temperature control of the pyrometer results in improved measurement accuracy, thereby improving process uniformity.

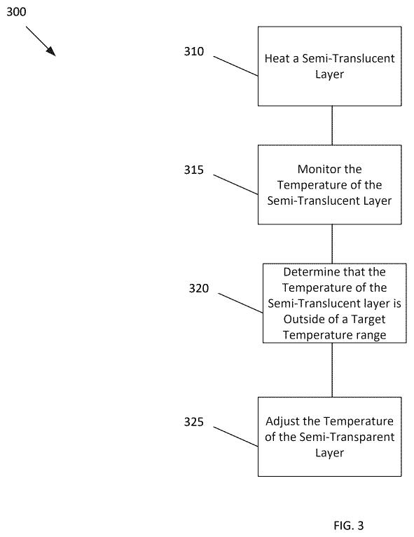

FIG. 3 is a schematic block diagram view of a method 300 of substrate processing, according to one or more embodiments.

Operation 310 of the method 300 includes heating a semi-translucent layer (e.g., semi-translucent layer 113 or semi-translucent layer 223). Heating the semi-translucent layer includes scanning the semi-translucent layer using the scanning laser system. Stated differently, heating the semi-translucent layer includes the controller (the controller 120 or the controller 290) steering laser devices (e.g., the first laser devices 142 or the laser devices 213) across the semi-translucent layer. As noted above, by heating the semi-translucent layer, a substrate (e.g., substrate 102 or 202) is heated using secondary radiation.

Operation 315 of the method 300 includes monitoring the temperature of the semi-translucent layer. The temperature of the semi-translucent layer may be monitored by one or more sensor devices and a corresponding controller. For example, the temperature of the semi-translucent layer may be monitored by the controller 120 using the sensor 147 (FIG. 1) or the controller 290 using the sensor devices 296, 297, 298, 299 (FIG. 2). In one or more embodiments, the transparency of the SiC material of the semi-translucent layer allows the one or more sensor devices to sense the radiation (heat) from both the substrate and the semi-translucent layer. Each of the sensor devices can provide the temperature of a different location of the semi-translucent layer and the substrate. The controller is able to mathematically decouple the readings from the one or more sensor devices using any suitable method such as figure print data.

Operation 320 of the method 300 includes determining that the temperature of the semi-translucent layer is outside of a target temperature range. The temperature of the semi-translucent layer is determined in operation 315 described above. In one or more embodiments, the target temperature range of the semi-translucent layer is about 0° C. to about 75° C., such as about 50° C., higher than the temperature of the substrate or the susceptor (susceptor 106 and susceptor 206). In one or more embodiments, the temperature of the substrate (or the susceptor) is less than 850° C. In one or more embodiments, the temperature of the semi-translucent layer is within the target temperature range when the temperature readings by the sensor devices indicate that the temperature of the semi-translucent layer is between about 0° C. to about 75° C. higher than the temperature of the substrate.

Operation 325 of the method 300 includes adjusting the temperature of the semi-translucent layer. In one or more embodiments, operation 330 is optional. If, during operation 320, the controller determines that the temperature of the semi-translucent layer is not within the target temperature range, then the temperature of the semi-translucent layer is adjusted. If during operation 320, the controller determines that the temperature of the semi-translucent layer is within the target temperature range, then operation 325 is skipped. The adjusting is performed by the controller 120 or the controller 290. The adjusting includes changing the power of the laser devices. For example, if the one or more sensor devices detect that the temperature of the semi-translucent layer is above the target temperature range, the controller reduces the power of the laser devices. If the temperature of the semi-translucent layer is below the target temperature range, the controller increases the power of the laser devices.

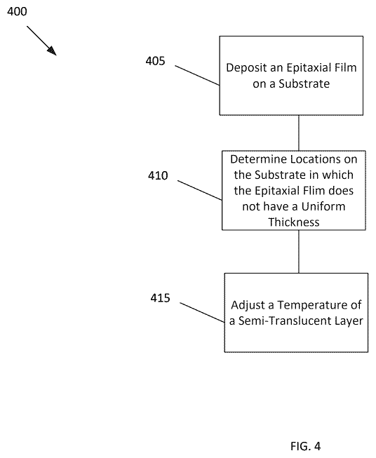

FIG. 4 is a schematic block diagram view of a method 400 of substrate processing, according to one or more embodiments. The method 400 is described with reference to FIG. 2.

Operation 405 includes depositing an epitaxial film on the substrate 202. The epitaxial film may be deposited in the same manner described above.

Operation 410 includes determining locations on the substrate 202 where the epitaxial film has a non-uniform thickness. The locations on the substrate 202 in which the epitaxial film has a non-uniform thickness are locations on the substrate 202 in which the epitaxial film is different compared to other locations on the substrate. Stated differently, the locations on the substrate 202 where the epitaxial film has a non-uniform thickness are locations on the substrate 202 in which the thickness of the epitaxial film is different than a target thickness. In one or more embodiments, the thickness of the epitaxial film may be measured using ellipsometry, Fourier Transform Infrared (FTIR) reflectometry, or any other suitable measurement method.

Operation 415 includes adjusting the temperature of the semi-translucent layer during deposition of the epitaxial film on a subsequent substrate. In one or more embodiments, the scanning laser system adjusts the temperature of the semi-translucent layer 223 during deposition of the epitaxial film on a subsequent substrate. Increasing the temperature at a location of the substrate can enhance epitaxial film growth. Therefore, adjusting the temperature of the semi-translucent layer 223 includes the controller 290, using the reflective mirrors 203, steering the laser devices 213 to location(s) of the semi-translucent layer 223 that are located above the location(s) of the substrate 202 where the epitaxial film had a non-uniform thickness. Advantageously the location(s) of the semi-translucent layer 223 that the laser devices 213 are steered to will provide additional secondary radiation to the location(s) of the subsequent substrate, resulting in uniform epitaxial film growth on the subsequent substrate. In one or more embodiments, operations 410 and 415 are optional if the epitaxial film is uniform across the substrate 202.

In one or more embodiments, the thickness of the epitaxial film can be measured in-situ during processing using one or more eddy sensors or coupons within the processing chamber. Therefore, in some embodiments, the temperature of the semi-translucent layer 223 can be adjusted dynamically during deposition on the substrate 202 to fix non-uniform growth of the epitaxial film during deposition.

As noted above, the semi-translucent layers on the isolation plate (e.g., isolation plate 111a and/or 271a) and/or the wavelengths of the laser devices (e.g., the first laser devices 142 and the laser devices 213) allow for the heating of a substrate using secondary radiation (heating the substrate using secondary heating). The semi-translucent layer absorbs the energy (heat) generated by the laser devices and heat radiates off the semi-translucent layer and heats the substrate (secondary radiation). Furthermore, the scanning laser system allows for adjusting and directing of the laser beams provided by the laser devices to keep the semi-translucent layer, and therefore, the substrate within a target temperature range. The scanning laser system allows for the fine tuning of the temperature of the semi-translucent layer, and therefore, the substrate to allow for more uniform growth of films on the substrate. Furthermore, by heating the substrate using secondary radiation in and/or controlling the heating of the substrate protects the substrate from side effects of direct heating (defects) and allows for a wider spectrum of heating using different precursors.

Benefits of the present disclosure include a semi-translucent layer disposed on an isolation plate, laser devices, and/or additional components of a scanning laser system that allow for controlled heating of the isolation plate. For example, the benefits include heating a semi-translucent layer formed on an isolation plate and using the secondary radiation from the semi-translucent layer to heat a substrate. The semi-translucent layer prevents lasers of certain wavelengths (e.g., the wavelengths of the first laser devices 142 and the laser devices 213) from penetrating the semi-translucent layer and directly heating the substrate. The heat generated by the laser devices heat the semi-translucent layer and secondary radiation is provided from the semi-translucent layer to the substrate. Furthermore, the laser scanning system allows adjusting and controlling of the heating of the semi-translucent layer to maintain the semi-translucent layer within a target temperature range to control the thickness of the epitaxial film. The scanning laser system allows for the fine tuning of the temperature of the semi-translucent layer, and therefore, allows for uniform growth of an epitaxial film on a substrate.

It is contemplated that one or more aspects disclosed herein may be combined. As an example, one or more aspects, features, components, operations and/or properties of the processing chamber 100, the first laser devices 142, the controller the processing chamber 200, the laser scanning system (the sensors 296, 297, 298, 299, the laser devices 213, the reflective mirrors 203, and the controller 290), and the method 300 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber comprising:
a chamber body;
a lid disposed over the chamber body;
one or more first laser devices disposed over the lid, the one or more first laser devices configured to emit light having a wavelength of about 380 nm to about 600 nm;
a first isolation plate disposed within an internal volume that is at least partially defined by the chamber body; and
a semi-translucent layer disposed over the first isolation plate, the semi-translucent layer configured to absorb at least part of the light emitted from the one or more first laser devices.

2. The processing chamber of claim 1, wherein the semi-translucent layer comprises a silicon carbide (SiC) material.

3. The processing chamber of claim 2, wherein the SiC material is 4-H SiC or 6-HSiC.

4. The processing chamber of claim 1, further comprising a second isolation plate positioned above the semi-translucent layer.

5. The processing chamber of claim 1, wherein a second laser device having a wavelength of about 800 nm to about 1000 nm is able to pass through the semi-translucent layer.

6. The processing chamber of claim 1, wherein the one or more first laser devices have a first polarization wavelength of about 450 nm to about 475 nm or a second polarization wavelength of about 580 nm to about 620 nm.

7. The processing chamber of claim 1, wherein the absorbing of at least part of the light emitted from the one or more first laser devices by the semi-translucent layer provides secondary radiation used to heat a substrate.

8. The processing chamber of claim 1, further comprising a scanning laser system configured to control and monitor a temperature of the semi-translucent layer, the scanning laser system comprising:
the one or more first laser devices;
one or more sensor devices disposed on, under, or within the lid, the one or more sensor devices configured to monitor the temperature of the semi-translucent layer;
reflective mirrors that are aligned with each of the one or more first laser devices; and
a controller coupled to the one or more first laser devices, the one or more sensor devices, and the reflective mirrors, the controller configured to adjust the temperature of the semi-translucent layer based on a determination that the temperature of the semi-translucent layer is outside of a target temperature range, wherein adjusting the temperature of the semi-translucent layer comprises adjusting a power of the one or more first laser devices.

9. The processing chamber of claim 8, wherein the one or more sensor devices are pyrometers.

10. A method comprising:
depositing an epitaxial film on a first substrate in a processing chamber, the processing chamber comprising:
one or more laser devices;
a semi-translucent layer disposed over the first substrate, the semi-translucent layer configured to absorb at least a portion of the light emitted from the one or more laser devices; and
a scanning laser system comprising:
the one or more laser devices;
reflective mirrors that are aligned with each of the one or more laser devices; and
a controller coupled to the one or more laser devices and the reflective mirrors;
determining the epitaxial film has a non-uniform thickness, the determining that the epitaxial film has the non-uniform thickness comprising determining one or more locations on the first substrate in which the thickness of the epitaxial film is different than a target thickness; and
adjusting a temperature of the semi-translucent layer, the adjusting of the semi-translucent layer comprising steering, by the controller using the reflective mirrors, the one or more laser devices to one or more locations on the semi-translucent layer that correspond to the one or more locations of the first substrate in which the thickness of the epitaxial film is different than the target thickness during deposition of the epitaxial film on a subsequent substrate.

11. The method of claim 10, wherein the semi-translucent layer comprises a silicon carbide (SiC) material.

12. The method of claim 10, wherein the SiC material is 4-H SiC or 6-H SiC.

13. The method of claim 10, wherein the one or more laser devices are configured to emit light having a wavelength of about 380 nm to about 600 nm.

14. The method of claim 10, wherein the processing chamber further comprises an isolation plate positioned below the semi-translucent layer.

15. The method of claim 10, wherein the absorbing of at least the portion of the light emitted from the one or more laser devices provides secondary radiation used to heat the first substrate.

16. The method of claim 15, wherein the one or more laser devices have a first polarization wavelength of about 450 nm to about 475 nm or a second polarization wavelength of about 580 nm to about 620 nm.

17. A method for processing a substrate comprising:
determining a temperature of a semi-translucent layer disposed over an isolation plate of a processing chamber using one or more sensors; and
based on determining that the semi-translucent layer is outside of a target temperature range, adjusting the temperature of the semi-translucent layer by adjusting a power of one or more laser devices, the one or more laser devices configured to emit light having a wavelength of about 380 nm to about 600 nm, and the semi-translucent layer configured to absorb at a portion of the light emitted by the one or more laser devices.

18. The method of claim 17, wherein the semi-translucent layer comprises a silicon carbide (SiC) material.

19. The method of claim 18, wherein the SiC material is 4-H SiC or 6-HSiC.

20. The method of claim 17, wherein adjusting the temperature of the semi-translucent layer further comprises adjusting, by a controller, a power of the one or more laser devices.
